(19) United States
(12) Patent Application Publication
(10) Pub. No.: US 2006/0225641 A1
(43) Pub. Date: Oct. 12, 2006

(54) Method for the production of monocrystalline structures and component

(76) Inventors: Georg Bostanjoglo, Berlin (DE); Ursus Kruger, Berlin (DE); Jan Steinbach, Berlin (DE)

Correspondence Address: John P. Musone;Siemens Corporation, Intellectual Property Department, 170 Wood Avenue South, Iselin, NJ, 08830, US

(21) Appl. No.: 10/541,691

(22) PCT Filed: Dec. 15, 2003
(86) PCT No.: PCT/EP03/14255

§ 371 Date: Apr. 13, 2006

(30) Foreign Application Priority Data
Jan. 10, 2003 (EP) 03000446.9

(51) Int. Cl. C30B 25/00; C30B 28/12; C30B 28/14

(52) U.S. Cl. 117/84

(57) ABSTRACT

According to prior art, structural errors in substrates in epitactic crystal growth are often carried over from the substrate on which the new material is to be deposited. This leads to a reduction in mechanical properties. According to the method, an intermediate layer is deposited prior to the deposition of epitactic material. Said intermediate layer prevents structural errors in the substrate from being carried over to the newly filled area.

### CROSS REFERENCE To RELATED APPLICATIONS

This application is the US National Stage of International Application No. PCT/EP2003/014255, filed Dec. 15, 2003 and claims the benefit thereof. The International Application claims the benefits of European application No. 03000446.9 EP filed Jan. 10, 2003, all of the applications are incorporated by reference herein in their entirety.

### FIELD OF INVENTION

The invention relates to a process for producing single-crystal structures, in particular from superalloys, in accordance with the preamble of the independent claims.

### BACKGROUND OF INVENTION

Metallic workpieces with a single-crystal structure or directionally solidified structures are used as components of machines which, in operation, are subject to high mechanical, thermal and/or chemical loads. By way of example, blades and vanes of gas turbines, in particular including rotor blades for aircraft engines, but also those used in stationary gas turbines, are produced from single crystals. Single-crystal workpieces of this type are manufactured, for example, by directional solidification from the melt. This involves casting processes in which the liquid metal alloy solidifies directionally or to produce a single-crystal structure, i.e. a single-crystal workpiece. By way of example, there is a special known casting process for the production of workpieces of this type in which the liquid alloy in a ceramic mould acquires a crystal orientation in a directional temperature field, e.g. of a Bridgeman furnace. Dendritic crystals are oriented in the direction of heat flow and form either a columnar crystal grain structure (i.e. grains which run over the entire length of the workpiece and are referred to here, in accordance with the general specialist terminology, as directionally solidified) or a single-crystal structure, i.e. the entire workpiece consists of a single crystal.

In these processes, it is necessary to avoid the transition to globular (polycrystalline) solidification, in which as a result of non-directional growth it is inevitable that transverse and longitudinal grain boundaries will form, which negate the good properties of the directionally solidified or single-crystal component.

Where the present document refers to single-crystal structure and single-crystal structures, this is to be understood as true single crystals which do not have any grain boundaries and crystal structures which do have grain boundaries running in the longitudinal direction but no grain boundaries running in the transverse direction. The latter crystalline structures are also referred to as directionally solidified microstructures.

Where the general term directionally solidified microstructures is used, this is to be understood as meaning both single crystals which do not have any grain boundaries or at most have small-angle grain boundaries, as well as columnar crystal structures, which do have grain boundaries running in the longitudinal direction, but do not have any transverse grain boundaries.

Examples of alloys used for the abovementioned single-crystal turbine blades and vanes include what are known as superalloys based on nickel (Ni), cobalt (Co) or iron (Fe). In particular nickel-based superalloys have excellent mechanical and chemical high-temperature properties.

These components become worn and damaged in use but can be refurbished by the worn regions affected being removed if necessary and new material applied again in these regions (for example epitaxially). However, the same crystal structure should be produced again.

A process of this type is described in U.S. Pat. No. 6,024,792 and in EP 0 892 090 A1. In this process, a layer of the material which is to be applied is applied in adjacent tracks transversely with respect to the length of the surface to be treated. This often leads to misalignments, since structures which are not in single crystal form, representing misalignments, are present in the vicinity of the surface immediately after production and use.

The structure of the material to be applied, however, is oriented on the basis of the structure of the surface to which it is applied, so that misalignments also occur in the applied material.

Consequently, the mechanical properties in this region are lacking, which has an adverse effect on the mechanical load-bearing capacity of the component as a whole.

### SUMMARY OF INVENTION

Therefore, it is an object of the invention to overcome the abovementioned drawback.

The object is achieved by a process as claimed in the claims by an intermediate layer being applied to the substrate.

With the new type of process, it is possible to build up on the, for example, directionally solidified structure of a substrate one or more layers or a body or a workpiece having the same directionally solidified structure as the substrate. This is an epitaxial process (epitaxial is to be understood as meaning the equi-oriented crystal growth on a crystalline base).

A globular microstructure is avoided by suitable process control through the application of an intermediate layer.

The invention provides a new type of process by which it is possible to build up one or more layers or a body or a workpiece with a single-crystal structure on a substrate with a single-crystal structure or single-crystal structures. This is an epitaxial process in which the crystalline structure of the substrate is also adopted by the layer or layers which are built up.

Hitherto, there has been no way of repairing or reconditioning a single-crystal workpiece in such a way that the single-crystal microstructure of the base material is also present in the reconditioned area without a large number of undesirable crystal orientations occurring.

With the novel process, it is now possible to recondition damaged and worn single-crystal workpieces in single-crystal form, i.e. to supplement and rebuild the optimum crystal structure. In this case, the substrate, e.g. for a single-crystal rotor blade, is built up and rebuilt layer by layer in single-crystal form on a track until the original size and shape of the workpiece has been restored.

The process for building up single crystals from the same material approximately the same material or also materials that differ from the substrate makes it possible, for example, to reconstruct or supplement workpieces which have single-crystal structures and have been damaged or have become worn. By way of example, nowadays there are rotor blades of gas turbines which consist of single crystals of what are known as metal superalloys and which can be repaired by the process if they have been damaged.

Although single-crystal workpieces can be produced from the melt by directional solidification, despite their excellent properties even those parts produced by directional solidification do become worn.

With the novel process, it is now possible to recondition damaged and worn single-crystal workpieces in single crystal form, i.e. to supplement and rebuild the crystal structure. In this case, the substrate, e.g. for a single-crystal rotor blade, is built up and rebuilt layer by layer in single-crystal form until the original size and shape of the workpiece has been restored.

Suitable energy or heat sources for carrying out the process are laser beams or electron beams i.e. energy sources with which it is possible to introduce high quantities of energy over a large area or in a large volume.

The beam with a high energy and energy density is directed onto the surface of the substrate, so that a surface layer of the substrate is slightly melted. The material is fed to the working region of the beam, for example in powder form or in the form of a wire. The material supplied is likewise melted. The melting of this supplied material may take place in the liquid bath of the molten surface layer or on the way to the liquid bath. The procedure preferably takes place under shielding gas and/or in vacuo.

If the solidification of the melt takes place under conditions which are outside the globular range, i.e. in the range in which the material used is directionally solidified, the material solidifies in single-crystal form, i.e. grows as an epitaxial structure on the substrate. Metals are described as having solidified in globular form if the melt does not crystallize in directional form. In this case, it is inevitable that one or more grain boundaries will be formed at the transition from “directionally single-crystal” to “non-directional”, and these grain boundaries negate the advantages of the single crystal.

The single-crystal structure is expediently applied layer by layer in the form of thin films, plates or complex forms of approximately one millimeter or a fraction of a millimeter on top of one another.

If the substrate is brought to a preheating temperature in the range from 600° C. to 1100° C. by blind tracking, i.e. without the supply of material, using the laser or induction means, and this temperature is maintained for example while the material is being built up, the stresses in the substrate and in the built-up single crystal, but also between the substrate and the crystalline structure which has been built up epitaxially thereon, are reduced, which contributes to preventing recrystallization and creep in the crystal structure.

Stress-relief annealing of substrate and the single crystal layer which has been rebuilt for about 1 hour at a temperature in the range from approximately 1000° C. to 1250° C., for CMSX-4 at approx. 1150° C., followed by slow cooling, reduces internal stresses, which could destroy the single-crystal structures through recrystallization and creep. However, the stress-relief annealing could also take place immediately after the application of the epitaxial layer using an RF device.

The so-called GV diagram is different for different metals and metal alloys and can be calculated for each alloy or determined experimentally. The curve L in the GV diagram separates the region of the two parameters solidification rate and temperature gradient in which the alloy solidifies in globular form from the region of the two parameters in which the alloy solidifies to form a dendritically directional microstructure. A description and explanation of the GV diagram is to be found, for example, in Material Science, Engineering Band 65 1984, in Publication J. D. Hunt on “Columnar to Equiangular Transition”.

A further object is achieved by a component as claimed the claims, in which an intermediate layer is present on the substrate.

### BRIEF DESCRIPTION OF THE DRAWINGS

Exemplary embodiments are shown in the figures, in which:

FIGS. 1, 2, 3, 4 show various process steps involved in a process according to the invention.

### DETAILED DESCRIPTION OF INVENTION

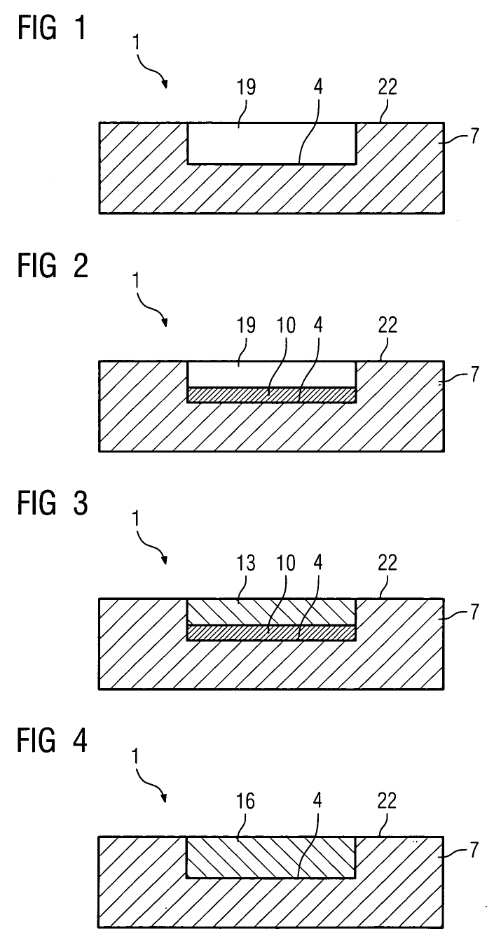

FIG. 1 shows a component 1, in particular a component for a gas turbine, such as for example a turbine blade or vane, which comprises a substrate 7.

The substrate 7 is in particular a nickel-based or cobalt-based metallic superalloy and in particular has a single-crystal structure.

New material, which is to have a single-crystal structure similar to or exactly the same as that of the substrate 7, is to be introduced either on the surface 22 of the component or in a recess 19 in the component 1.

The recess 19 is, for example, a location on the component 1 at which material has been removed on account of the presence of corrosion and/or cracks. These degraded regions were removed without leaving any residues and need to be refilled, the aim being for them to have the same mechanical properties as the substrate 7.

FIG. 2 shows the component 1 in a further process step. According to the invention, an intermediate layer 10 is applied to the base surface 4 in the recess 19 or on the surface 22. The intermediate layer 10 can be applied in various ways by a first material application process, in particular by an electrochemical deposition process (for example electrolysis), but not by a process which is known from EP 892 090 A1.

The intermediate layer 10 consists, for example, of nickel and/or nickel/cobalt and/or nickel/cobalt/chromium, (main constituents of the substrate 7); the nickel, cobalt or chromium contents of the intermediate layer 10 having, for example, approximately the same ratios as the main constituents of the material of the substrate 7.

However, the intermediate layer 10 may also have the same composition as or a similar composition to the material of the substrate 7.

There may be structure defects in the crystal structure (not corrosion or degradation) of the blade or vane at the base surface 4, formed during the degradation. Therefore, when applying new material, there is a risk of the structure defects, e.g. globular grains, being copied, and of the material which is to be applied in single-crystal form in the recess 19 not in fact adopting a single crystal structure.

The intermediate layer 10 prevents structure defects in the component 1 at the base surface 4 from being copied and allows epitaxial growth on the intermediate layer.

FIG. 3 shows a further process step of the process according to the invention.

New material 13, which has the same structure or a similar structure to the substrate 7 of the component 1, has been added to the intermediate layer 10 in a known way by means of an epitaxial material application process (for example laser build-up welding, as known from EP 892 090 A1).

During the epitaxial growth, the structure of the new material 13 is oriented not on the basis of the possibly unfavorable

structure of the substrate 7, but rather on the basis of the structure of the intermediate layer 10.

As a result of the deposition of the intermediate layer 10, for example by electro-deposition (with a non-directional and/or directional microstructure), it is possible to produce at least directional structures irrespective of the base (in polycrystalline form).

It is also possible to correct orientation defects resulting from DS and SX structures by suitable selection of the deposition parameters.

The process for applying the intermediate layer 10 differs from the process used to apply the layer 13.

Given a suitable selection of material and thickness of the intermediate layer 10, the introduction of heat into the substrate 7 is reduced, with the result that the remelting of the single-crystal blade or vane at the surface 4, 22 associated with the epitaxial growth process is minimized.

The recess 19 was in this case filled, for example, up to the surface 22 of the component 1 in the vicinity of the recess 19.

FIG. 4 shows a further, optional process step of the process according to the invention.

A heat treatment after or even during the laser build-up welding causes the material of the intermediate layer 10 and of the layer 13, and for example also of the substrate 7, to diffuse, so that the original composition of the intermediate layer 10 partly or completely disappears and together with the layer 13 and/or the substrate 7 forms a region 16 which at least in part has a crystalline structure. Any differences in the material composition

of the layers 10, 13 also balance themselves out.

The region 16, which now completely fills the recess 19, has a single-crystal structure and has similar or identical, in particular mechanical properties to the substrate 7.

If the intermediate layer 10 is sufficiently thin, this layer disappears altogether.

1.-10. (canceled)

11. A process for producing single-crystal structures from metallic superalloys, comprising:
providing a substrate with a single-crystal structure from a epitaxial growth of a layer material via a first material application process;
applying an intermediate layer where no single-crystal or directional structure occurs on the substrate; and
epitaxially growing the layer material on the intermediate layer.

12. The process as claimed in claim 11, wherein the structure is a component, a workpiece, a blade, or a vane.

13. The process as claimed in claim 11, wherein the substrate has a plurality of single-crystal structures from the epitaxial growth of the layer material.

14. The process as claimed in claim 11, wherein a heat treatment transforms at least part of the intermediate layer with the substrate into a region having a crystalline structure.

15. The process as claimed in claim 11, wherein a heat treatment transforms at least part of the intermediate layer with the layer material into a region having a crystalline structure.

16. The process as claimed in claim 11, wherein the intermediate layer is generated electrochemically.

17. The process as claimed in claim 11, wherein the intermediate layer is applied with a non-directional microstructure.

18. The process as claimed in claim 11, wherein the intermediate layer is applied with a directional microstructure.

19. The process as claimed in claim 11, wherein the intermediate layer is applied via a second material application process.

20. The process as claimed in claim 11, wherein a composition ratio of constituents for the intermediate layer is adapted to a main composition ratio of main constituents of the substrate.

21. The process as claimed in claim 11, wherein a material composition of the intermediate layer at least approximately corresponds to the material composition of the substrate.

22. A component formed from a metallic superalloy, comprising:
a substrate having at least partially single-crystal structures;
an intermediate layer having no single-crystal or directional structure in the substrate; and
a layer material with a single-crystal structure is present on the intermediate layer.

23. The component as claimed in claim 22, wherein a composition of the layer material at least approximately corresponds to a material composition of the substrate.

24. The process as claimed in claim 22, wherein the intermediate layer is generated electrochemically.
